(19) United States
(12) Patent Application Publication
(10) Pub. No.: US 2007/0286944 A1
(43) Pub. Date: Dec. 13, 2007

(54) FABRICATION OF FULL-COLOR OLED PANEL USING MICRO-CAVITY STRUCTURE

(75) Inventors: Meiso Yokoyama, Asaka-shi (JP); Guan-Ting Chen, Shanhua Town (TW); Wei-Chen Zhan, Jhuolan Town (TW)

Correspondence Address: PAI PATENT & TRADEMARK LAW FIRM, 1001 FOURTH AVENUE, SUITE 3200, SEATTLE, WA, 98154, US

(73) Assignee: ITC INC., LTD., Asaka-shi (JP)

(21) Appl. No.: 11/469,848

(22) Filed: Sep. 1, 2006

(30) Foreign Application Priority Data
Jun. 13, 2006 (TW) 95120922

(51) Int. Cl. B05D 5/12; B05D 5/06

(52) U.S. Cl. 427/66

(57) ABSTRACT

Methods of making top-emitting or bottom-emitting full-color OLED flat panel using micro-cavity structure for primary colors are disclosed. The primary colors are realized by setting a different thickness for the hole injection layer of the OLEDs for each primary color, while keeping the thickness of the hole transport layer, the emission layer, the electron transport layer the same for all the OLEDs. Steps for predetermining the respective thickness of the hole injection layer for each primary color are also disclosed.

### BACKGROUND OF THE INVENTION

1. Field of the Invention

The invention describe that we use the micro-cavity structure to design the full-color organic light-emitting diodes (OLED) flat panel. In other words, by using the method of micro-cavity to reconcile the color with white-light organic electro-luminescence device(OLED), we can control the thickness of the hole injection layer to mediate the optical length of RGB cavity to get the light of red, green and blue without using the color filter. This invention not only can simplify the traditional manufacture process of the full-color OLED flat panel, but also high color-saturated and high brightness full-colored OLED flat panel.

2. Description of the Related Art

The OLED undergo continuous research and efforts for many years, because of the benefits of self-emission, high responsive speed, and low power consumption, OLED eventually outshine other flat panels. And the fast growth of full-color manufacture procedure and commercialization, accelerate the trend of commercialization of full-colored OLED.

There are many different technology methods can apply on the full-color OLED flat panel display up to now. The most prevailing methods include: (a) RGB side-by-side pixilation; (b) color conversion medium; and (c) color filter.

### (A) RGB Side-by-Side Pixelation:

This technology is to put the red, blue and green OLED side by side on the substrate as RGB primary color. The company of Kodak got the patent of this method in 1991. This method is a much more mature processing technology, and this technology is the basis of all no matter the size of molecule. For example, both the earliest trial and commercial manufacture product are use of this technology. The representative companies that development this technology include Kodak, Pioneer, Epson and Toshiba, the firm of Taiwan also advocate this technology as core of development. This method use the shadow mask to cover the other two pixels while evaporating one of the red, blue, green organic materials, and then use the high-precision localization system to move the mask or substrate, and repeat these steps to evaporate the other two pixels.

While fabricating the high-precision flat panel, the pixels size and pixel to pixel pitch will be very small. The precise of localization system, the error of the aperture of mask, and the blocking and pollution of mask will play the most important key role. The mean system error of commercialized machine is ±5 μm. And the metamorphosis according to temperature will also affect the precise of localization. The common mask used to evaporate the pixels is composed of nickel or stainless steel. The thermal expansion of nickel and stainless steel are 12.8 ppm/° C. and 17.3 ppm/° C. respectively, but still larger 2 to 3 times than the glass substrate (5 ppm/° C.) of EL flat panel. Therefore, development of the low thermal expansion evaporating mask is the first of all.

### (B) Color Conversion Medium, CCM:

Color conversion medium transfers the energy from blue light of blue OLED with fluorescent dye, and then release the red, blue, green primary color. This method can improve two problems of RGB side-by-side pixilation. One problem is that the different efficiency of the 3 device of RGB will need different design of the driving circuit. The other problem is that the different lifetime will conduce unequal of the color that will be compensated with the circuit but then increase the difficulty of the process of manufacture. The representative companies that development this technology are Idemitsu Kosan and Fuji Electric Systems. In order to elevate the efficiency of color transfer, the Idemitsu Kosan replaced the light source with long wave white luminous. As result, the efficiency of color transfer elevated more than 20%. Because this method use the same producing technology with color filter, CCM elevates the precision much more than RGB side-by-side pixilation, and also improve higher ratio of product yielding. This method use the multi-band light source, therefore need one color filter to increase the color purity of pixel. The other problems that still want to resolve include how to increase the output ratio of light in multi-layer, such as CCM, CF and substrate, and how to improve the stability of blue light OLED and the inferiority of color change media.

(c) Color Filter, CF:

Full-color OLED using color filter method applies the full-coloring method of liquid crystal display (LCD). This technology uses the white luminous OLED, and applies the color filter to get the three primary color. The benefits and strength are same of the CCM. Because the using of only one kind of OLED source, the life time and brightness of RGB three primary color are the same. CF not only does not have the phenomenon of distortion, and not necessarily considers the problem of localization, but also can increase the resolution of screen. Hence, the CF has the potential to apply on the large size flat panel. In general, color filter will decrease about two third of the luminous intensity. Therefore, the development of highly efficient and stable white light is the precondition. The shortages of CF include the increased cost with color filter, and the lower efficiency of manufacture (i.e., small size flat panel). But the method of CF still has the most potentiality on the high resolution and large size flat panel currently. The representative companies that development this technology are TDK, Mitsubishi Chemical, and Sanyo.

In consideration of the application of OLED flat panel, full-color is one of the necessary components to succeed in the market. All above three methods have shortage on color saturation, emission efficiency or process of manufacture. Therefore, this invention use the white or green emission layer with controlling the length of optics of micro-cavity respectively to manufacture OLED flat panel that has easier process of manufacture and high color purity.

### BRIEF SUMMARY OF THE INVENTION

New methods of making top-emitting full-color OLED flat panels using micro-cavity structure for primary colors are disclosed in this invention. Such methods comprise the steps of: (a) providing a glass substrate; (b) depositing by evaporation over the glass substrate a matrix of reflective electrodes, each reflective electrode basing an OLED stack; (c) sequentially depositing by evaporation a plurality of organic layers over the reflective electrode of each OLED stack, said plurality of organic layers including a hole injection layer (HIL), a hole transport layer (HTL), an emission layer (EML) and an electron transport layer (ETL), wherein the thickness of each respective organic layer other than the HIL is substantially uniform for all the OLED stacks and the thickness of the HIL alternates in three predetermined values; and (d) depositing by evaporation a semi-reflective electrode over the ETL for each OLED stack. The organic layers of each OLED stack form a micro-cavity and the thickness of the HTL, EML and ETL and the three predetermined thicknesses of the HIL are set to adjust the optical length of the micro-cavity such that the three primary colors (RGB) are respectively realized.

New methods of making bottom-emitting full-color OLED flat panels using micro-cavity structure for primary colors are also disclosed in this invention. Such methods comprise the steps of: (a) providing a glass substrate; (b) providing over the glass substrate a matrix of transparent indium tin oxide (ITO) electrodes, each transparent ITO basing an OLED stack; (c) depositing by evaporation a semi-reflective electrode over the transparent ITO electrode of each OLED stack; (d) sequentially depositing by evaporation a plurality of organic layers over the semi-reflective electrode of each OLED stack, said plurality of organic layers including a hole injection layer (HIL), a hole transport layer (HTL), an emission layer (EML) and an electron transport layer (ETL), wherein the thickness of each respective organic layer other than the HIL is substantially uniform for all the OLED stacks and the thickness of the HIL alternates in three predetermined values; and (e) depositing by evaporation a reflective electrode over the ETL for each OLED stack. The organic layers and the semi-reflective electrode of each OLED stack form a micro-cavity and the thickness of the HTL, EML and ETL and the three predetermined thicknesses of the HIL are set to adjust the optical length of the micro-cavity such that the three primary colors (RGB) are respectively realized.

Similar methods are also disclosed for making top-emitting or bottom-emitting full-color flat panels with white OLEDs in addition to OLEDs for primary colors.

Steps are also disclosed for predetermining the respective thickness of the hole injection layer of the OLEDs for primary colors.

### BRIEF DESCRIPTION OF THE DRAWINGS

FIG. 1 is a cross-sectional schematic view of the top-emitting OLED with micro-cavity structure.

FIG. 2 is the simulated EL spectra of red, green, and blue light emitting with micro-cavity structure.

FIG. 3 is simulated EL spectra of red, green, and blue light emitting with color filter.

FIG. 4 is a cross-sectional schematic view of the bottom-emitting RGB full-color OLED of the invention.

FIG. 5 is a cross-sectional schematic view of the bottom-emitting WRGB full-color OLED of the invention.

FIG. 6 is a cross-sectional schematic view of the top-emitting RGB full-color OLED of the invention.

FIG. 7 is a cross-sectional schematic view of the top-emitting WRGB full-color OLED of the invention.

FIG. 8 is compare measured and simulated EL spectra of micro-cavity OLED with white light source.

FIG. 9 is compare measured and simulated CIE color coordinate of micro-cavity OLED with white organic electroluminescence.

FIG. 10 is the voltage-current density characteristics of micro-cavity OLED with white organic electroluminescence.

FIG. 11 is the luminance-current density characteristics of micro-cavity OLED with white organic electroluminescence.

FIG. 12 is compare measured and simulated EL spectra of micro-cavity OLED with green organic electroluminescence.

FIG. 13 is compare measured and simulated CIE color coordinate of micro-cavity OLED with green organic electroluminescence.

FIG. 14 is the voltage-current density characteristics of micro-cavity OLED with green organic electroluminescence.

FIG. 15 is the luminance-current density characteristics of micro-cavity OLED with green organic electroluminescence.

### DETAILED DESCRIPTION OF THE PREFERRED EMBODIMENTS

In this invention, the micro-cavity structure is used to manufacture the full-color OLED flat panel. The micro-cavity effect means the optical interference effect inside the OLED device, which provides an electrode with semi-reflective mirror at the location where light emission occurs. When photons emit from the light emitting layer, they will conduce interference between the total-reflective electrode and the semi-reflective mirror. Hence, only a specific wavelength will be enhanced, and some others will be diminished. The most prominent characteristic of micro-cavity effect is that a specific wavelength will be enhanced; therefore, the full width at half maximum (FWHM) of the photo wave will become narrow.

The method we use to design the full-color OLED flat panel uses the micro-cavity structure in combination with the white-light or green-light light emitting layer and control the thickness of the hole injection layer (HIL) to adjust the optical length of the RGB micro-cavity to get the light of red, green and blue without using the color filter. This method not only can simplify the traditional manufacturing process of the full-color OLED flat panel, but also can obtain full-color OLED flat panel with high color saturation and high luminance.

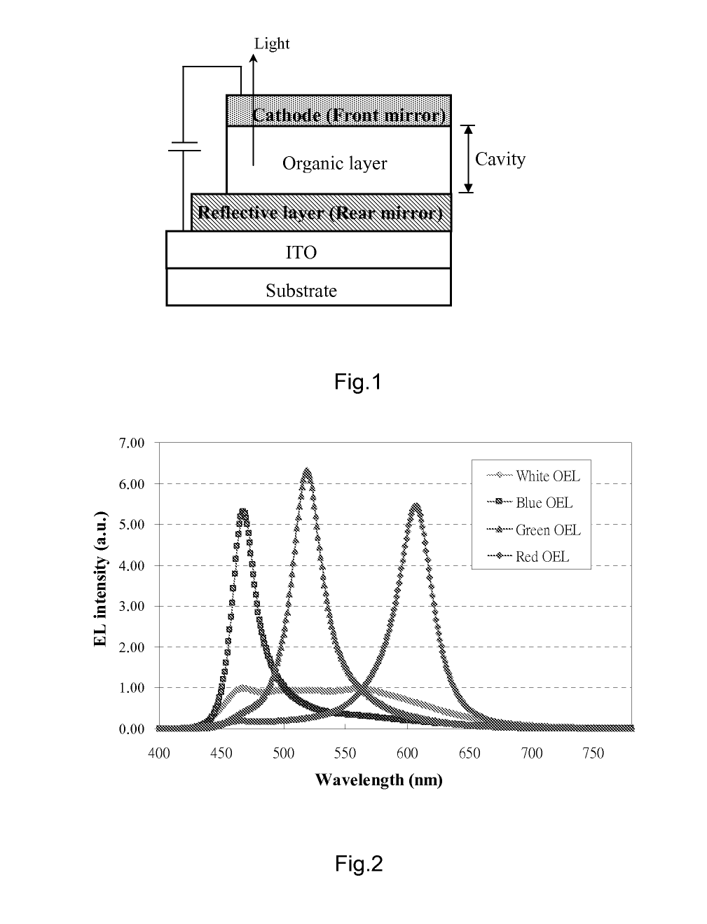

The micro-cavity effect of micro-cavity structure used to manufacture the full-color OLED flat panel can be considered as one kind of Fabry-Perot cavity as shown in FIG. 1.

In FIG. 1, the micro-cavity of top-emitting OLED is formed between the total-reflective layer (Rear Mirror) and the semi-reflective cathode (Front Mirror), and the micro-cavity is filled up with transparent metal and organic layers. The external emission spectrum intensity I(λ) of the micro-cavity at wavelength λ is calculated by formula (1):

$$I ( λ ) = \frac{( 1 - {R}_{f} ) [ 1 + {R}_{r} + 2 \sqrt{{R}_{r}} cos ( \frac{4 π Z}{λ} ) ]}{1 + {R}_{f} {R}_{r} - 2 \sqrt{{R}_{f} {R}_{r}} cos ( \frac{4 π L}{λ} )} {I}_{0} ( λ ) \qquad ( 1 )$$

where I₀(λ) is the emission spectrum intensity of the light emitting diode in the free space, L is the total optical length of the micro-cavity, Z is the effective optical distance between the emission layer and rear mirror, R_{f} and Rᵣ are the reflectivity of the semi-reflective front mirror and the total-reflective rear mirror, respectively. The light is designed to exit through the front mirror. After taking into account the effective penetration depth into the metal, the total optical length of the micro-cavity, L, is expressed by formula (2):

$$L = \sum {n}_{i} {l}_{i} + \vert \frac{λ}{4 π} \sum {ϕ}_{m i} \vert \qquad ( 2 )$$

where nᵢ and lᵢ are the refractive index and the thickness of an organic layer or the ITO layer, denoted by i., and φₘ is the phase shift at either of the metal mirrors. φₘ is given by formula (3):

$${ϕ}_{m} = arc tan ( \frac{2 {n}_{s} {k}_{m}}{{n}_{s}^{2} - {n}_{m}^{2} - {k}_{m}^{2}} ) \qquad ( 3 )$$

where nₘ and kₘ are the real and imaginary parts of the refractive index of the respective metal mirror, and nₛ is the refractive index of the material in contact with the metal. The values of these refractive indexes are wavelength dependent.

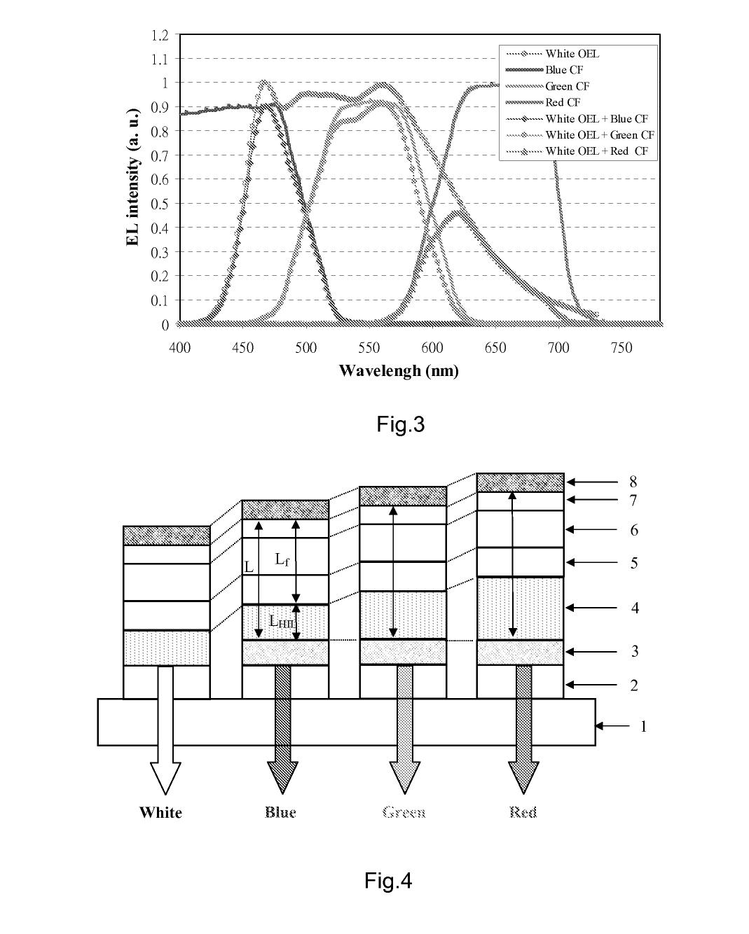

Both FIGS. 2 & 3 simulate the same full-wave white luminous spectrum, and apply the micro-cavity in FIG. 1 and the color filter (CF) method, respectively, to get the luminous spectrum of blue, green, and red. We set the reflectivity (Rᵣ) of the total-refletive electrode at 100%, the reflectivity of the semi-reflective electrode (R_{f}) at 60%, the effective distance between the emissin layer and the total-reflective electrode (Z) at 70 nm, the refractive indexes (n) of the hole injection layer, the light emitting layer of white OEL, and the electron transport layer at 1.7, 1.7, and 1.8, respectively, the thickness of the hole injection layer of blue, green and red pixels at 200 nm, 230 nm, and 260 nm, respectively, the thickness of the light emitting layer of white OEL at 45 nm, and thickness of the electron transport layer at 20 nm, respectively. As a result, we get the blue, green, and red luminous spectrum as FIG. 2 from formula (1) and formula (2). The blue, green, and red luminous spectrum as shown in FIG. 3 is obtained from using the same intensity of white luminous spectrum as in FIG. 2 through the CF method for traditional LCD flat panel.

Comparing the blue, green, and red luminous spectrum of FIG. 2 and FIG. 3, we found that given the same intensity of white luminous spectrum, the FWHM of blue, green, and red luminous spectrum obtained with the micro-cavity structure is narrower than it is with the CF method. Dividing the integral of the blue, green, and red luminous spectrum from FIG. 2 and FIG. 3 by the integral of the white luminous spectrum gives the luminance ratio of blue, green, and red light to white light with the method of micro-cavity as 4.36, 6.16, and 5.88, respectively. Whereas the luminance ratio of blue, green, and red light to white light with the CF method is 0.262, 0.473, and 0.19, respectively.

From the results above, we predict that the micro-cavity can produce blue, green, and red light OLED with higher color purity and higher luminance than the CF method.

The method of micro-cavity structure used to manufacture the full-color OLED flat panel for the structure of bottom-emitting OLED is shown in FIG. 4. The bottom-emitting W, R, G, B full-color OLED flat panel includes a glass substrate 1, a transparent indium tin oxide (ITO) electrode 2 set on the glass substrate 1, and layers deposited sequentially by evaporation: a semi-reflective metal anode 3, a hole injection layer 4 with different thickness for each color, a hole transport layer 5, an emission layer 6, an electron transport layer 7, and a total-reflective metal cathode 8. The only difference between the white pixels and the red, green, blue pixels is that the former lacks the semi-reflective metal anode 3. The total-reflective metal cathode 8 is highly reflective, whereas the metal anode 3 is a semi-reflective electrode. The micro-cavity effect can be controlled by changing the thickness of the hole injection layer 4 to manufacture the bottom-emitting full-color OLED flat panel with red, green and blue light. The thickness of all the other organic layers can also be adjusted to control the micro-cavity effect. However, the thickness of each of those layers is usually kept the same for all the OLED pixels.

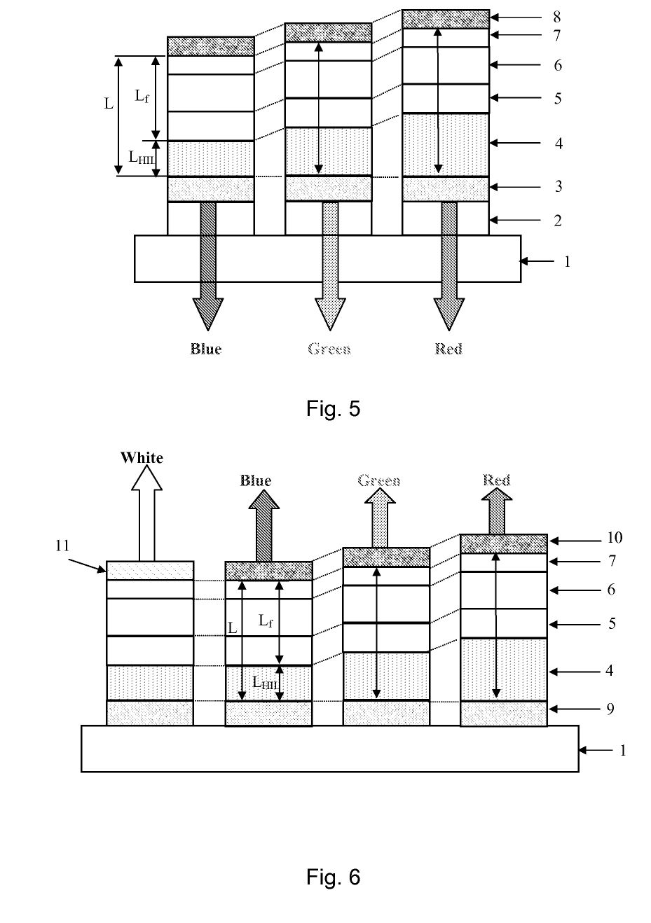

Additionally, the full-color OLED flat panel with micro-cavity in this invention also can be manufactured from the RGB primary color as same as RGB side by side pixelation method. As shown in FIG. 5, the bottom-emitting full-color OLED must include a glass substrate 1, a transparent ITO electrode 2 set on the glass substrate 1, and layers deposited sequentially by evaporation: a semi-reflective metal anode 3, a hole injection layer 4 with different thickness for each color, a hole transport layer 5, an emission layer 6, an electron transport layer 7, and a total-reflective metal cathode 8. The red, green and blue lights of this OLED flat panel are obtained from the micro-cavity structure.

Alternatively, the method of micro-cavity structure in this invention can be applied to manufacture the WRGB top-emitting full-color OLED flat panel by changing the thickness of the hole injection layer to control the micro-cavity effect. As shown in FIG. 6, the top-emitting full-color OLED flat panel includes a glass substrate 1, and layers deposited sequentially by evaporation: a total-reflective metal anode 9, a hole injection layer 4 with different thickness for each color, a hole transport layer 5, an emission layer 6, an electron transport layer 7, and a semi-reflective metal cathode 10 for blue, green, and red pixels or a transparent cathode 11 for white OLED pixels. The semi-reflective metal cathode 10 usually uses Ca/Ag/SnO₂, LiF/Al/Ag, or Ca/Mg/ZnSe, whereas the transparent cathode 11 usually uses Al, Al/Li, Mg/Ag, LiO₂/Al, or LiF/Al. The red, green, and blue lights of this full-color OLED flat panel are obtained from application of the micro-cavity, and the white light is contributed by the independent white light OLED structure. The only difference between the white pixels and the red, green, and blue pixels is that the white OLED pixel must be paired with the transparent cathode 11. Therefore, during the WRGB top-emitting full-color OLED flat panel operation, because white light is contributed by the independent white light OLED, about 25% power consumption can be saved compared to other panels using the RGB structure.

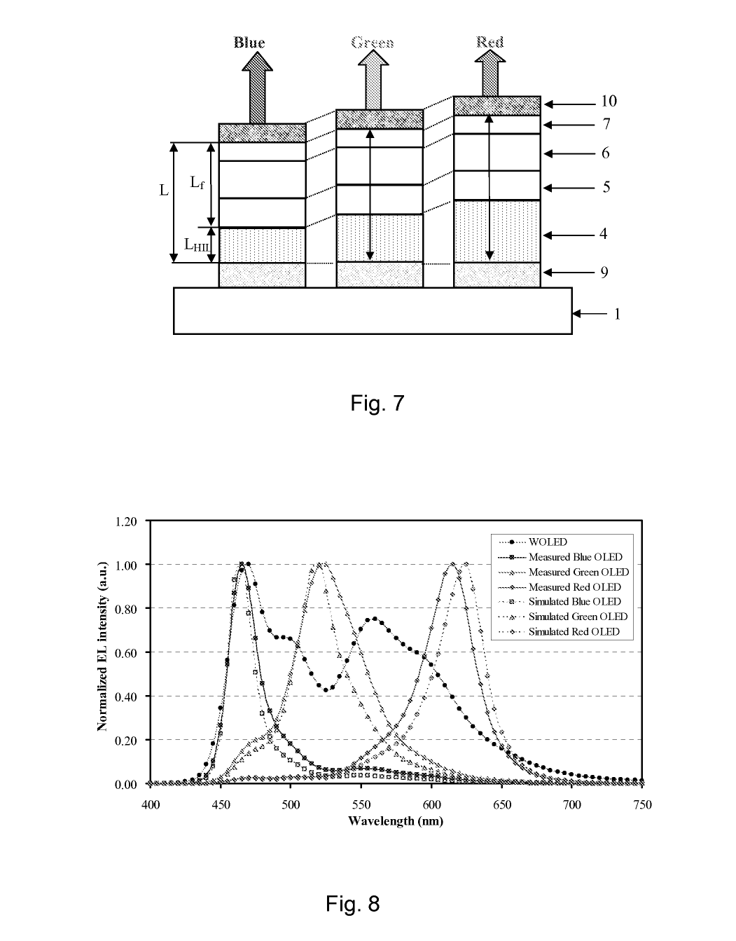

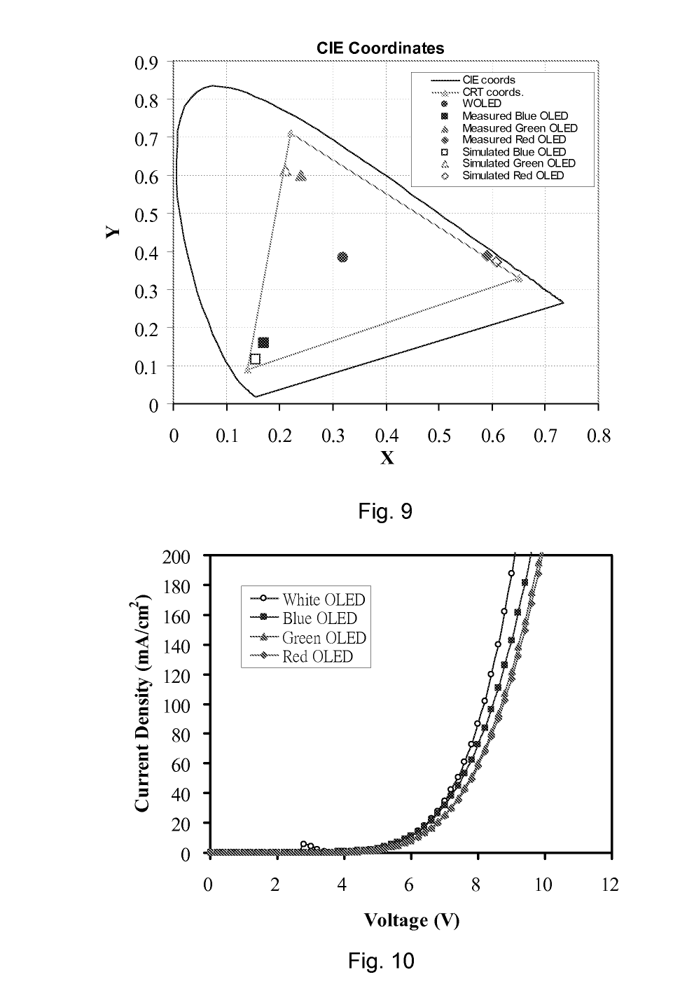

Similarly, the top-emitting full-color OLED flat panel with micro-cavity in this invention can be manufactured through the conventional RGB method as shown in FIG. 7. This full-color OLED flat panel includes a glass substrate 1, and layers deposited sequentially by evaporation: a total-reflective metal anode 9, a hole injection layer 4 with different thickness for each color, a hole transport layer 5, an emission layer 6, an electron transport layer 7, and a semi-reflective metal cathode 10. Similarly, the red, green, and blue lights are obtained by using the micro-cavity structure.

The material of the hole injection layer 4 used to manufacture the full-color OLED flat panel in this invention can be selected from the organic materials such as CuPc, TiOPc, 2T-NATA, m-MTDATA etc., and an appropriate concentration of F4-TCNQ can be added into the hole injection layer 4 to efficiently elevate the luminous efficiency of the full-wave white light OLED.

The N-type organic materials, such as C60, Alq₃, BPhen, NTCDA, PTCDA, and MePTCDI, can be used for the electron transport layer 7, and Li, Cs or BEDT-TTF, can be added to help with the injection of the electron into organic layer and elevate the efficiency of electron transporting.

Ag, Ag/AgOx, Ag/MnOx, Ag/CFx, or Au can be used to form the semi-reflective metal anode 3 in the bottom-emitting full-color OLED, and Mg:Ag (10:1), Ag/Li, Al, LiF/Al can be used to form the total-reflective metal cathode 8.

And for top-emitting full-color OLED, Ag, Ag/AgOx, Ag/MnOx, or Ag/CFx can be used to form the total-reflective metal anode 9, and LiF/Al/Ag, LiF/Al/Ag/Alq₃, LiF/Al/Al:SiO, Ca/Mg/ZnSe, Ca/Ag, Ca/Ag/SnO₂. can be used to form the semi-reflective metal cathode 10.

Furthermore, the mobility of holes in the micro-cavity structure of this invention can be enhanced by adding F4-TCNQ to the hole injection layer 4. On the other hand, the efficiency of hole injection can be enhanced through tunneling of the holes because the F4-TCNQ will cause the energy band bending. Adding F4-TCNQ to the hole injection layer 4 will lower the initial voltage and stability, while the electric characteristic of this device will not change with different thickness of hole injection layer 4.

The characteristic of the micro-cavity structure in this invention is that full-color OLED flat panel with high luminous efficiency and high color saturation can be manufactured by changing the thickness of the hole injection layer 4 to adjust the total optical length of the micro-cavity.

The scope of this invention is not limited to the above figures, but should also include embodiments with other types of structure such as for the emission layer and other materials as long as the changes are within the spirit of this invention.

### EXAMPLE 1

### Using White Organic Electroluminescence on Emission Layer 6

The example uses the bottom-emitting WRGB full-color OLED shown in FIG. 4. The hole injection layer 4 is m-MTDATA:F4-TCNQ (3%), and the thickness of white, blue, green and red light devices is 55 nm, 55 nm, 75 nm, and 105 nm, respectively. The structure of the emission layer 6 is NPB (15 nm)/NPB:Rubrene (5 nm)/DPVBi:BCzVBi (15 nm)/DPVBi:DCJTB (1 nm), and the electron transport layer 7 is Alq₃ (20 nm). The total-reflective metal cathode 8 is LiF (0.7 nm)/Al (180 nm), and the semi-reflective metal anode 3 is Ag (50 nm). The Ag membrane on the ITO electrode 2 of the blue, green, and red light OLEDs must be processed with 100 watt O₂ plasma for 30 to 180 seconds to increase the work function of Ag to enhance the efficiency of hole injection.

FIGS. 8 & 9 show the actual measured values and simulated values of electroluminescence spectrum and CIE chromaticity coordinates of white OLED under circuit of 50 mA/cm², and blue, green, and red OLED with micro-cavity structure using white organic electroluminescence layer with different thickness of hole injection layer respectively under circuit of 50 mA/cm². With the parameters set as below, the simulated data can be calculated from formulas (1) & (2). The reflectivity (Rᵣ) of the total-reflective electrode 8 is 100%, and the reflectivity (R_{f}) of the semi-reflective electrode 3 is 70%, the effective distance (Z) between the emission layer 6 and the reflective electrode 8 is 40 nm, the refractive indexes (n) of the hole injection layer 4, the white light OEL emission layer 6 and the electron transport layer 7 are 1.79, 1.9, and 1.9, respectively. And the total optical length (L) of the blue, green, and red OLEDs will be 230 nm (with thickness of hole injection layer 55 nm), 260.25 nm (with thickness of hole injection layer 75 nm), and 319.95 nm (with thickness of hole injection layer 105 nm) respectively.

From FIGS. 8 & 9, we found that when the thickness (x) of the hole injection layer 4 is set as 55 nm, 75 nm, and 105 nm for blue, green, and red OLED, the wave crest of the blue, green, and red OLED occurs at 465 nm, 520 nm, and 615 nm, and the corresponding CIE chromaticity coordinates are (0.17, 0.16), (0.24, 0.60) and (0.59, 0.39), respectively. And the color saturation attained is 56.8% as defined by the NTSC (National Television System Committee). Hence it can be proved that highly saturated blue, green, and red light OLED can be easily obtained through mediating the thickness of the hole injection layer of white light OLED with the structure of micro-cavity. By comparing the simulated and actual measured data, we find that the actual measured data are closely approximated by the simulated data from formulas (1) & (2).

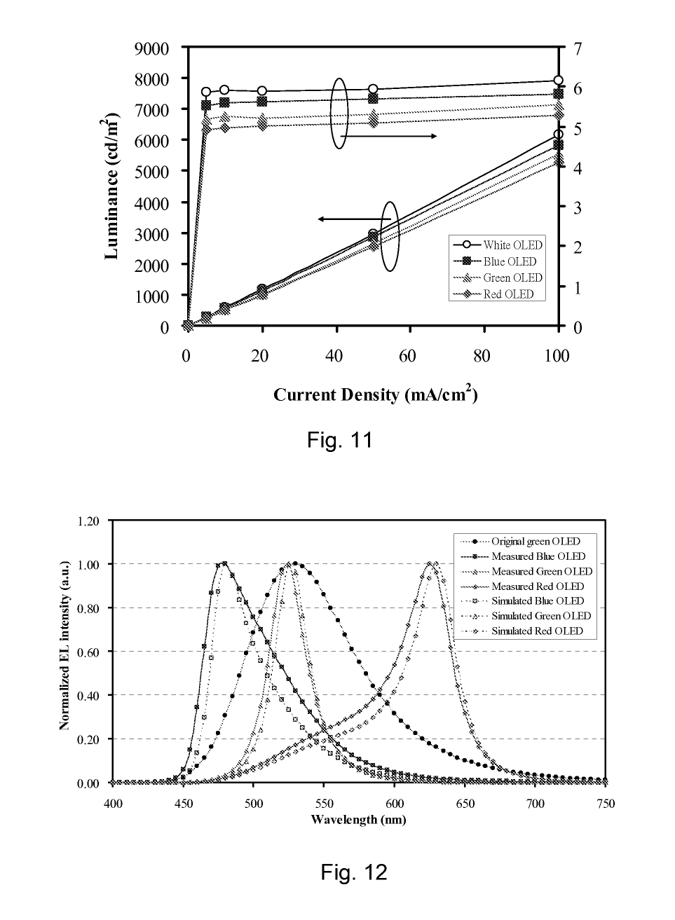

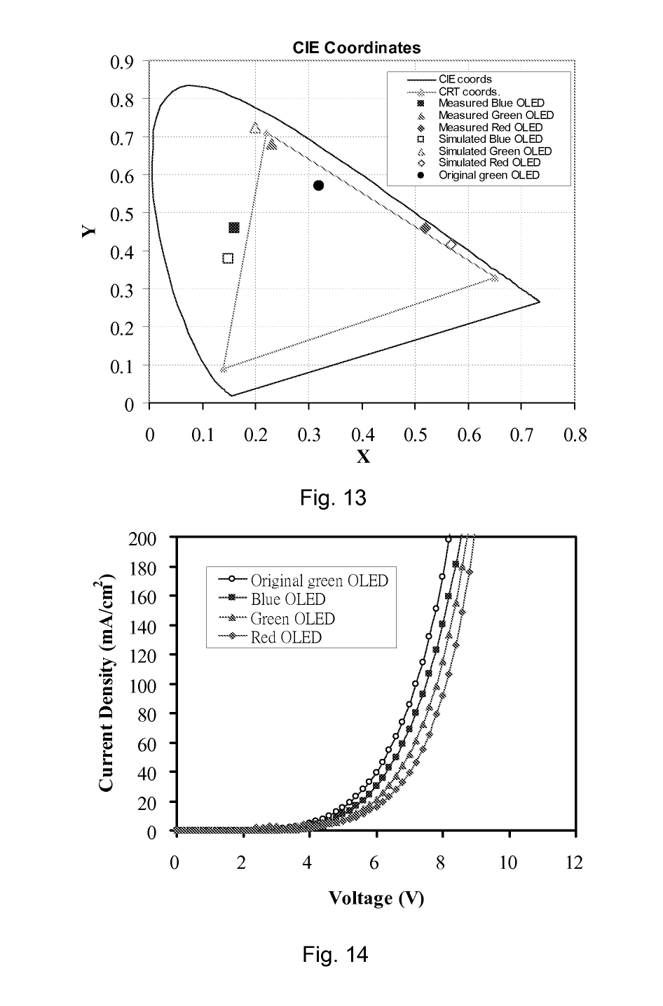

From the voltage-circuit density characteristics shown in FIG. 10, we find that the initial voltage of the blue, green, red, and white light OLED is about 5 voltages and the voltage does not change with different color of the emission. FIG. 11 shows the luminous intensity-circuit density-luminous efficiency. We find that when the circuit density is set at 20 mA/cm², the luminous intensity of blue, green, red and white OLED are 1124, 1041, 1002, and 1178 cd/m² respectively, and the luminous efficiency are 5.6, 5.2, 5.0 and 5.9 cd/A respectively.

### EXAMPLE 2

### Using Green Organic Electroluminescence on Emission Layer 6

On the other hand, the emission layer 6 in our invention also can use the green organic electroluminescence. We take the full-color bottom-emitting OLED in FIG. 5 as an example. The composition of the hole injection layer 4 is m-MTDATA:F4-TCNQ (3%) (x nm), and the thickness (x) for blue, green, and red light are 70 nm, 85 nm, and 115 nm, respectively. The structure of the emission layer 6 is NPB (20 nm)/Alq₃ (20 nm), and the electron transport layer 7 is Alq₃ (20 nm). The total reflective metal cathode 8 is LiF (0.7 nm)/Al (180 nm), and the semi-reflective metal anode 3 is Ag (50 nm). The Ag membrane on ITO 2 of the blue, green, and red light OLEDs must be processed with 100 watt O₂ plasma for 30 to 180 seconds to increase the work function of Ag to elevate the efficiency of hole injection.

FIGS. 12 & 13 show the actual measured values and simulated values of electroluminescence spectrum and CIE chromaticity coordinates of blue, green, and red OLEDs with micro-cavity structure using green organic electroluminescence layer and different thicknesses of hole injection layer 4 respectively under circuit of 50 mA/cm². With the parameters set as below, the simulated data can be calculated from formulas (1) & (2). The reflectivity (Rᵣ) of the total reflective electrode 8 is 100%, and the reflectivity (R_{f}) of the semi-reflective electrode 3 is 70%, the effective distance (Z) between the emission layer 6 and the reflective electrode 8 is 40 nm, the refractive index (n) of the hole injection layer 4, white light OEL emission layer 6 and electron transport layer 7 are 1.79, 1.9, and 1.9, respectively. And the total optical length (L) of the blue, green, and red OLEDs will be 237 nm (with thickness of hole injection layer 70 nm), 263.15 nm (with thickness of hole injection layer 85 nm), and 316.85 nm (with thickness of hole injection layer 115 nm) respectively.

From FIGS. 12 & 13, we found that when the thickness (x) of the hole injection layer 4 is set as 70 nm, 85 nm, and 115 nm, we can get the blue, green, and red OLEDs with wave crest as 480 nm, 525 nm, and 620 nm, and the corresponding CIE chromaticity coordinates are (0.16, 0.37), (0.19, 0.72) and (0.56, 0.42) respectively. And the color saturation attained is 46.6% as defined by the NTSC (National Television System Committee). Hence it can be proved that we can get the blue, green, and red light OLEDs easily through mediating the thickness of the hole injection layer 4 of white light OLED with the structure of micro-cavity, but the lower saturation of color. By comparing the simulated and actual measured data, we find that the actual measured data are very closely approximated by the simulated data from formulas (1) & (2).

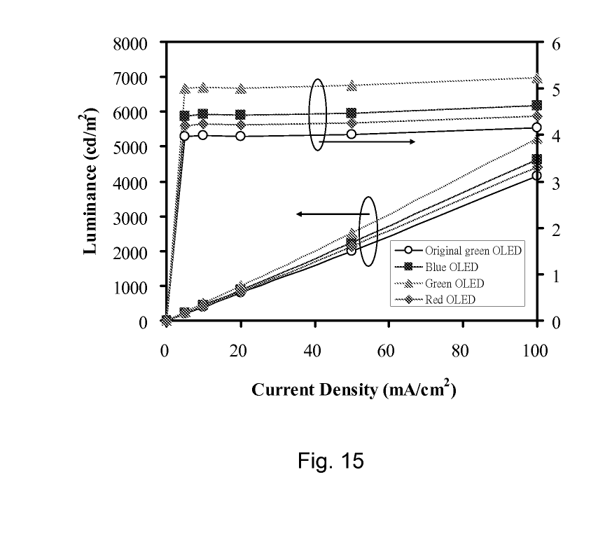

From the voltage-circuit density characteristics shown in FIG. 14, we find that the initial voltage of the blue, green, red, and white light OLED is about 4 voltages and the voltage will not change with the color of the emission. FIG. 15 shows the luminous intensity-circuit density-luminous efficiency. We find that while the circuit density is set as 20 mA/cm², the luminous intensity of blue, green, and red lights are 884, 1000, and 842 cd/M² respectively, and the luminous efficiency are 4.42, 5.01, and 4.21.

What is claimed is:

1. A method of making a top-emitting full-color OLED flat panel with micro-cavity structure for primary colors, comprising the steps of:
(a) providing a glass substrate;
(b) depositing by evaporation over the glass substrate a matrix of reflective electrodes, each reflective electrode basing an OLED stack and serving as an anode for the OLED stack;
(c) sequentially depositing by evaporation a plurality of organic layers over the reflective electrode of each OLED stack, said plurality of organic layers including a hole injection layer (HIL), a hole transport layer (HTL), an emission layer (EML) and an electron transport layer (ETL), wherein the thickness of each respective organic layer other than the HIL is substantially uniform for all the OLED stacks and the thickness of the HIL alternates in three predetermined values for every three consecutive OLED stacks in a same row; and
(d) depositing by evaporation a semi-reflective electrode over the ETL for each OLED stack, the semi-reflective electrode serving as a cathode for the OLED stack,
wherein the organic layers between the anode and the cathode of each OLED stack form a micro-cavity having an optical length and the respective thickness of the HTL, EML and ETL and the three predetermined thicknesses of the HIL are set to adjust the optical length of the micro-cavity such that the three primary colors (RGB) are respectively realized by every three consecutive OLED stacks in a same row.

2. The method of making a top-emitting full-color OLED flat panel with micro-cavity structure for primary colors of claim 1, wherein the three predetermined thicknesses of HIL, L_{HIL}, are determined by:
L_{HIL}L−L_{f} (1)
wherein L_{f} is the total thickness of the organic layers other than the HIL, and L is the optical length of the micro-cavity according to formulas (2) and (3):
$$L = \sum {n}_{i} {l}_{i} + \vert \frac{λ}{4 π} \sum {ϕ}_{m i} \vert \qquad ( 2 )$$
where nᵢ and lᵢ are the refractive index and the thickness of the organic layers, λ is the wavelength of each of the three primary colors, and φₘ is the phase shift at the reflective electrode or the semi-reflective electrode according to
$${ϕ}_{m} = arc tan ( \frac{2 {n}_{s} {k}_{m}}{{n}_{s}^{2} - {n}_{m}^{2} - {k}_{m}^{2}} ) \qquad ( 3 )$$
where nₘ and kₘ are the real and imaginary parts of the refractive index of the respective electrode, and nₛ is the refractive index of the organic layer in contact with the respective electrode.

3. The method of making a top-emitting full-color OLED flat panel with micro-cavity structure for primary colors of claim 1, further comprising:
(e) providing a color filter over the semi-reflective electrode of each OLED stack for improving color saturation.

4. The method of making a top-emitting full-color OLED flat panel with micro-cavity structure for primary colors of claim 1, wherein the reflective electrode is made of Ag/ITO, Ag/AgOx, Ag/MnOx, or Ag/CFx; and the semi-reflective electrode is made of LiF/Al/Ag, LiF/Al/Ag/Alq₃, LiF/Al/Al:SiO, Ca/Mg/ZnSe, Ca/Ag, Ca/Ag/SnO₂.

5. A method of making a top-emitting full-color OLED flat panel with micro-cavity structure for primary colors of claim 1, wherein the reflective index of the semi-reflective electrode provided is between 0.1% and 70%.

6. A method of making a top-emitting full-color OLED flat panel with white OLED and micro-cavity structure for primary colors, comprising the steps of:
(a) providing a glass substrate;
(b) depositing by evaporation over the glass substrate a matrix of reflective electrodes, each reflective electrode basing an OLED stack and serving as an anode for the OLED stack;
(c) sequentially depositing by evaporation a plurality of organic layers over the reflective electrode of each OLED stack, said plurality of organic layers including a hole injection layer (HIL), a hole transport layer (HTL), an emission layer (EML) and an electron transport layer (ETL), wherein the thickness of each respective organic layer other than the HILis substantially uniform for all the OLED stacks and the thickness of the HIL alternates in four predetermined values for every four consecutive OLED stacks in a same row, said four consecutive OLED stacks being a white OLED stack and three RGB OLED stacks, respectively;
(d) depositing by evaporation a semi-reflective electrode over the ETL for each RGB OLED stack, the semi-reflective electrode serving as a cathode for the RGB OLED stack; and
(e) depositing by evaporation a transparent electrode over the ETL for each white OLED stack, the transparent electrode serving as a cathode for the white OLED stack,
wherein a white color is realized by the white OLED stacks and the organic layers between the anode and the cathode of each RGB OLED stack form a micro-cavity having an optical length and the respective thickness of HTL, EML and ETL and the three predetermined thicknesses of the HIL for the RGB OLED stacks are set to adjust the optical length of the micro-cavity such that the three primary colors (RGB) are realized by the RGB OLED stacks respectively.

7. The method of making a top-emitting full-color OLED flat panel with white OLED and micro-cavity structure for primary colors of claim 6, wherein the three predetermined thicknesses of HIL, L_{HIL}, are determined by:
L_{HIL}=L−L_{f} (1)
wherein L_{f} is the total thickness of the organic layers other than the HIL, and L is the optical length of the micro-cavity according to formulas (2) and (3):
$$L = \sum {n}_{i} {l}_{i} + \vert \frac{λ}{4 π} \sum {ϕ}_{m i} \vert \qquad ( 2 )$$
where nᵢ and lᵢ are the refractive index and the thickness of the organic layers, λ is the wavelength of each of the three primary colors, and φₘ is the phase shift at the reflective electrode or the semi-reflective electrode according to
$${ϕ}_{m} = arc tan ( \frac{2 {n}_{s} {k}_{m}}{{n}_{s}^{2} - {n}_{m}^{2} - {k}_{m}^{2}} ) \qquad ( 3 )$$
where nₘ and kₘ are the real and imaginary parts of the refractive index of the respective electrode, and nₛ is the refractive index of the organic layer in contact with the respective electrode.

8. The method of making a top-emitting full-color OLED flat panel with white OLED and micro-cavity structure for primary colors of claim 6, further comprising:
(f) providing a color filter over the semi-reflective electrode of each RGB OLED stack for improving color saturation.

9. The method of making a top-emitting full-color OLED flat panel with white OLED and micro-cavity structure for primary colors of claim 6, wherein the reflective electrode is made of Ag/ITO, Ag/AgOx, Ag/MnOx, or Ag/CFx; and the semi-reflective electrode is made of LiF/Al/Ag, LiF/Al/Ag/Alq₃, LiF/Al/Al:SiO, Ca/Mg/ZnSe, Ca/Ag, Ca/Ag/SnO₂.

10. The method of making a top-emitting full-color OLED flat panel with white OLED and micro-cavity structure for primary colors of claim 6, wherein the transparent electrode for the white OLED stacks is made of Al, Al/Li, Mg/Ag, LiO₂/Al, or LiF/Al.

11. A method of making a top-emitting full-color OLED flat panel with white OLED and micro-cavity structure for primary colors of claim 6, wherein the reflective index of the semi-reflective electrode provided is between 0.1% and 70%.

12. A method of making a bottom-emitting full-color OLED flat panel with micro-cavity structure for primary colors, comprising the steps of:
(a) providing a glass substrate;
(b) providing over the glass substrate a matrix of transparent indium tin oxide (ITO) electrodes, each transparent ITO basing an OLED stack;
(c) depositing by evaporation a semi-reflective electrode over the transparent ITO electrode of each OLED stack, the semi-reflective electrode serving as an anode for the OLED stack;
(d) sequentially depositing by evaporation a plurality of organic layers over the semi-reflective electrode of each OLED stack, said plurality of organic layers including a hole injection layer (HIL), a hole transport layer (HTL), an emission layer (EML) and an electron transport layer (ETL), wherein the thickness of each respective organic layer other than the HIL is substantially uniform for all the OLED stacks and the thickness of the HIL alternates in three predetermined values for every three consecutive OLED stacks in a same row; and
(e) depositing by evaporation a reflective electrode over the ETL for each OLED stack, the reflective electrode serving as a cathode for the OLED stack,
wherein the organic layers between the anode and the cathode of each OLED stack form a micro-cavity having an optical length and the respective thickness of the HTL, EML and ETL and the three predetermined thicknesses of the HIL are set to adjust the optical length of the micro-cavity such that the three primary colors (RGB) are respectively realized by every three consecutive OLED stacks in a same row.

13. The method of making a bottom-emitting full-color OLED flat panel with micro-cavity structure for primary colors of claim 12, wherein the three predetermined thicknesses of HIL, L_{HIL}, are determined by:
L_{HIL}=L−L_{f} (1)
wherein L_{f} is the total thickness of the organic layers other than the HIL, and L is the optical length of the micro-cavity according to formulas (2) and (3):
$$L = \sum {n}_{i} {l}_{i} + \vert \frac{λ}{4 π} \sum {ϕ}_{m i} \vert \qquad ( 2 )$$
where nᵢ and lᵢ are the refractive index and the thickness of the organic layers, λ is the wavelength of each of the three primary colors, and φₘ is the phase shift at the reflective electrode or the semi-reflective electrode according to
$${ϕ}_{m} = arc tan ( \frac{2 {n}_{s} {k}_{m}}{{n}_{s}^{2} - {n}_{m}^{2} - {k}_{m}^{2}} ) \qquad ( 3 )$$
where nₘ and kₘ are the real and imaginary parts of the refractive index of the respective electrode and nₛ is the refractive index of the organic layer in contact with the respective electrode.

14. The method of making a bottom-emitting full-color OLED flat panel with micro-cavity structure for primary colors of claim 12, wherein the semi-reflective electrode is made of Ag, said method further comprising:
providing a color filter between the semi-reflective electrode and the ITO electrode of each OLED stack for improving color saturation.

15. The method of making a bottom-emitting full-color OLED flat panel with micro-cavity structure for primary colors of claim 12, wherein the reflective electrode is made of Ag/Li, Mg/Ag, Al, or LiF/Al; and the semi-reflective electrode is made of Ag, Ag/AgOx, Ag/MnOx, Ag/CFx, or Au.

16. A method of making a bottom-emitting full-color OLED flat panel with white OLED and micro-cavity structure for primary colors, comprising the steps of:
(a) providing a glass substrate;
(b) providing over the glass substrate a matrix of transparent indium tin oxide (ITO) electrodes, each transparent ITO electrode basing an OLED stack;
(c) for every four consecutive OLED stacks in a same row, depositing by evaporation a semi-reflective electrode over the transparent ITO electrode for the second through fourth OLED stacks (RGB OLED stacks), the first OLED stack not deposited with a semi-reflective electrode being a white OLED stack;
(d) sequentially depositing by evaporation a plurality of organic layers over the semi-reflective electrode for each RGB OLED stack and over the transparent ITO electrode for each white OLED stack, said plurality of organic layers including a hole injection layer (HIL), a hole transport layer (HTL), an emission layer (EML) and an electron transport layer (ETL), wherein the thickness of each respective organic layer other than the HIL is substantially uniform for all the OLED stacks and the thickness of the HIL alternates in four predetermined values for every four consecutive OLED stacks in a same row; and
(e) depositing by evaporation a reflective electrode over the ETL for each OLED stack,
wherein a white color is realized by the white OLED stacks and the organic layers between the transparent ITO electrode and the cathode of each RGB OLED stack form a micro-cavity having an optical length and the respective thickness of the HTL, EML and ETL and the three predetermined thicknesses of the HIL for the RGB OLED stacks are set to adjust the optical length of the micro-cavity such that the three primary colors (RGB) are realized by the RGB OLED stacks respectively.

17. The method of making a bottom-emitting full-color OLED flat panel with white OLED and micro-cavity structure for primary colors of claim 16, wherein the three predetermined thicknesses of HIL, L_{HIL}, are determined by:
L_{HIL}=L−L_{f} (1)
wherein L_{f} is the total thickness of the organic layers other than the HIL, and L is the optical length of the micro-cavity according to formulas (2) and (3):
$$L = \sum {n}_{i} {l}_{i} + \vert \frac{λ}{4 π} \sum {ϕ}_{m i} \vert \qquad ( 2 )$$
where nᵢ and lᵢ are the refractive index and the thickness of the organic layers, λ is the wavelength of each of the three primary colors, and φₘ is the phase shift at the reflective electrode or the semi-reflective electrode according to
$${ϕ}_{m} = arc tan ( \frac{2 {n}_{s} {k}_{m}}{{n}_{s}^{2} - {n}_{m}^{2} - {k}_{m}^{2}} ) \qquad ( 3 )$$
where nₘ and kₘ are the real and imaginary parts of the refractive index of the respective electrode and nₛ is the refractive index of the organic layer in contact with the respective electrode.

18. The method of making a bottom-emitting full-color OLED flat panel with white OLED and micro-cavity structure for primary colors of claim 16, wherein the semi-reflective electrode is made of Ag, said method further comprising:
providing a color filter between the semi-reflective electrode and the ITO electrode of each RGB OLED stack for improving color saturation.

19. The method of making a bottom-emitting full-color OLED flat panel with white OLED and micro-cavity structure for primary colors of claim 16, wherein the reflective electrode for the RGB OLED stacks is made of Ag/Li, Mg/Ag, Al, or LiF/Al; and the semi-reflective electrode is made of Ag, Ag/AgOx, Ag/MnOx, Ag/CFx, or Au.

20. The method of making a bottom-emitting full-color OLED flat panel with white OLED and micro-cavity structure for primary colors of claim 16, wherein the reflective electrode for the white OLED stacks is made of Al, Al/Li, Mg/Ag, LiO₂/Al, or LiF/Al.
